(19) United States
(12) Patent Application Publication
(10) Pub. No.: US 2014/0076355 A1
(43) Pub. Date: Mar. 20, 2014

(54) TREATMENT APPARATUS, METHOD FOR MANUFACTURING TREATMENT LIQUID, AND METHOD FOR MANUFACTURING ELECTRONIC DEVICE

(71) Applicant: Kabushiki Kaisha Toshiba, Minato-ku (JP)

(72) Inventors: Hideaki HIRABAYASHI, Kanagawa-ken (JP); Yuji NAGASHIMA, Kanagawa-ken (JP); Masaaki HIRAKAWA, Kanagawa-ken (JP)

(73) Assignee: Kabushiki Kaisha Toshiba, Minato-ku (JP)

(21) Appl. No.: 13/968,672

(22) Filed: Aug. 16, 2013

(30) Foreign Application Priority Data
Sep. 20, 2012 (JP) 2012-207599

(51) Int. Cl. H01L 21/02

(52) U.S. Cl. CPC H01L 21/02041
USPC 134/3; 134/115 R; 510/175

(57) ABSTRACT

According to one embodiment, a treatment apparatus includes an electrolysis unit, an alkali addition unit, and a treatment unit. The electrolysis unit includes an anode electrode and a cathode electrode. The electrolysis unit is configured to electrolyze a solution containing an alkali containing no metal, hydrochloric acid, and water. The alkali addition unit is configured to further add the alkali containing no metal to a solution that has undergone the electrolysis. The treatment unit is configured to perform treatment of an object to be treated using a solution that has undergone the electrolysis and in which the alkali containing no metal is further added.

### CROSS-REFERENCE TO RELATED APPLICATIONS

This application is based upon and claims the benefit of priority from Japanese Patent Application No. 2012-207599, filed on Sep. 20, 2012; the entire contents of which are incorporated herein by reference.

### FIELD

Embodiments described herein relate generally to a treatment apparatus, a method for manufacturing treatment liquid, and a method for manufacturing electronic device.

### BACKGROUND

There is a technique in which chlorine gas is supplied to an aqueous solution of TMAH (tetramethylammonium hydroxide, (CH₃)₄NOH) to manufacture a treatment liquid containing TMAOCl (tetramethylammonium hypochlorite).

However, using chlorine gas requires attention to the handling of the chlorine gas. Furthermore, controllability in manufacturing processes is not good in the method in which chlorine gas is supplied to an aqueous solution of TMAH to manufacture a treatment liquid.

Hence, it has been desired to enhance the productivity of treatment liquid.

### BRIEF DESCRIPTION OF THE DRAWINGS

FIG. 1 is a schematic diagram for illustrating a treatment apparatus 1 according to a first embodiment;

FIG. 2 is a graph for illustrating characteristics of the treatment liquid 130;

FIG. 3 is a graph illustrating relationships between the concentration of hypochlorous acid and the time of being allowed to stand in the case where the hydrogen ion exponent of the treatment liquid 130 is pH 10;

FIG. 4 is a graph for illustrating the treatment capacity of the treatment liquid in the case where the hydrogen ion exponent is pH 10;

FIGS. 5A and 5B are graphs for illustrating the influence of the treatment liquid on the surface of a silicon wafer;

FIG. 6 is a graph for illustrating the influence of the treatment liquid on the roughness of the surface of the silicon wafer;

FIG. 7 is a graph for illustrating the organic substance removal capacity of the treatment liquid;

FIG. 8 is a graph for illustrating the organic substance removal capacity of the treatment liquid;

FIG. 9 is a graph for illustrating the silicon oxide removal capacity of the treatment liquid;

FIG. 10 is a graph for illustrating the electrolysis efficiency in the electrolysis unit 14;

FIG. 11 is a schematic diagram for illustrating a treatment apparatus la according to a second embodiment;

FIG. 12 is a graph for illustrating the treatment capacity in the case where ammonia is added;

FIG. 13 is a graph for illustrating the influence of ammonia addition;

FIGS. 14A and 14B are schematic views for illustrating the position of alkali addition; and

FIG. 15 is a flow chart for illustrating a method for manufacturing a treatment liquid according to the third embodiment.

### DETAILED DESCRIPTION

In general, according to one embodiment, a treatment apparatus includes an electrolysis unit, an alkali addition unit, and a treatment unit. The electrolysis unit includes an anode electrode and a cathode electrode. The electrolysis unit is configured to electrolyze a solution containing an alkali containing no metal, hydrochloric acid, and water. The alkali addition unit is configured to further add the alkali containing no metal to a solution that has undergone the electrolysis. The treatment unit is configured to perform treatment of an object to be treated using a solution that has undergone the electrolysis and in which the alkali containing no metal is further added.

Hereinbelow, embodiments are described with reference to the drawings. In the drawings, like components are marked with the same reference numerals, and a detailed description is omitted as appropriate.

### First Embodiment

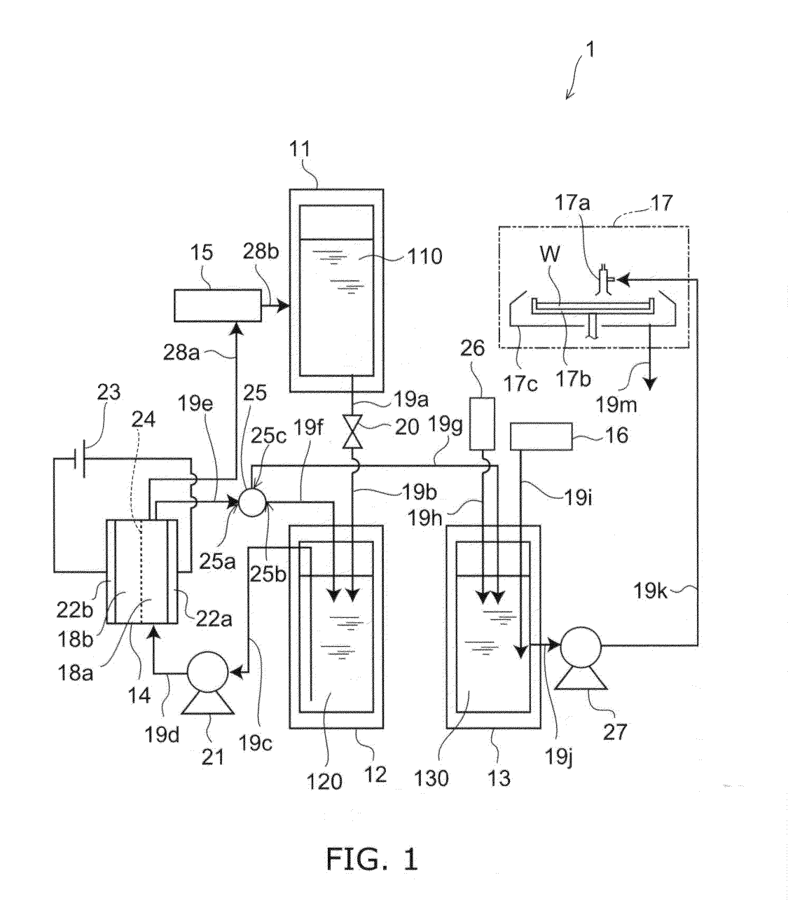

FIG. 1 is a schematic diagram for illustrating a treatment apparatus 1 according to a first embodiment.

As shown in FIG. 1, a tank 11 (corresponding to an example of a second tank), a tank 12 (corresponding to an example of a first tank), a tank 13, an electrolysis unit 14, a chlorine gas recovery unit 15, an alkali addition unit 16, and a treatment unit 17 are provided in the treatment apparatus 1.

The tank 11 stores a solution 110.

The solution 110 may be a source liquid used for the manufacturing of a treatment liquid.

Here, the treatment apparatus 1 can be used in, for example, the manufacturing process of an electronic device such as a semiconductor device and a flat panel display.

In the case of being used in the manufacturing process of an electronic device, it is necessary that metal ions such as sodium ions not be contained in the treatment liquid.

Thus, the solution 110 does not contain metal ions such as sodium ions. The solution 110 is, for example, a solution containing an alkali containing no metal, hydrochloric acid, and water. The alkali containing no metal is, for example, an organic alkali such as TMAH and choline, ammonia, or the like.

Two or more kinds of alkali containing no metal may be contained in the solution 110.

One end of a pipe 19a is connected to the tank 11. A valve 20 is connected to the other end of the pipe 19a. One end of a pipe 19b is connected to the valve 20. The other end of the pipe 19b is connected to the tank 12. The valve 20 may be, for example, a solenoid valve or the like. The solution 110 stored in the tank 11 can flow into the tank 12 via the pipe 19a, the valve 20, and the pipe 19b. The valve 20 enables the starting and stopping of the inflow of the solution 110, the control of the inflow amount, etc. A supply unit such as a pump may be provided to supply the solution 110 stored in the tank 11 to the tank 12.

In the tank 12, the solution 110 supplied from the tank 11 is stored in the beginning. As described later, the solution 110 is electrolyzed in the electrolysis unit 14 into a solution 120. The solution 120 circulates between the tank 12 and the electrolysis unit 14. By the solution 120 being electrolyzed in the electrolysis unit 14, hypochlorous acid (HClO) is produced. Thus, the solution 120 stored in the tank 12 has the same components as the solution 110 in the beginning, but the concentration of hypochlorous acid in the solution 120 increases gradually.

One end of a pipe 19c is connected to the tank 12. A supply unit 21 such as a pump is connected to the other end of the pipe 19c. One end of a pipe 19d is connected to the supply unit 21. The other end of the pipe 19d is connected to the electrolysis unit 14.

The supply unit 21 supplies the solution 120 stored in the tank 12 to the electrolysis unit 14. The solution 120 supplied to the electrolysis unit 14 returns to the tank 12 via a three-way valve 25. Thus, the supply unit 21 circulates the solution 120 between the tank 12 and the electrolysis unit 14.

The solution 120 in which the concentration of hypochlorous acid has fallen within a prescribed range is supplied to the tank 13 via the three-way valve 25.

In this way, the supply unit 21 circulates the solution 120 between the tank 12 and the electrolysis unit 14, and supplies the solution 120 to the tank 13.

The electrolysis unit 14 electrolyzes the solution 120 to produce hypochlorous acid.

An anode chamber 18a, a cathode chamber 18b, an anode electrode 22a, a cathode electrode 22b, a DC power source 23, and a diaphragm 24 are provided in the electrolysis unit 14.

The anode chamber 18a and the cathode chamber 18b face each other across the diaphragm 24. The anode electrode 22a is provided in the anode chamber 18a. The anode electrode 22a is exposed in the anode chamber 18a, and is in contact with the solution 120. The anode side of the DC power source 23 is connected to the anode electrode 22a. The cathode electrode 22b is provided in the cathode chamber 18b. The cathode electrode 22b is exposed in the cathode chamber 18b, and is in contact with the solution 120. The cathode side of the DC power source 23 is connected to the cathode electrode 22b. The material of the anode electrode 22a and the cathode electrode 22b may contain, for example, glassy carbon, conductive diamond doped with boron, phosphorus, nitrogen, or the like, etc.

The diaphragm 24 is not necessarily needed, and the anode chamber 18a and the cathode chamber 18b may be integrally provided.

One end of a pipe 28a is connected to the electrolysis unit 14. The other end of the pipe 28a is connected to the chlorine gas recovery unit 15. One end of a pipe 28b is connected to the chlorine gas recovery unit 15. The other end of the pipe 28b is connected to the tank 11.

The chlorine gas recovery unit 15 recovers chlorine gas produced when the solution 120 is electrolyzed, and supplies the chlorine gas to the solution 110 stored in the tank 11. The chlorine gas supplied to the solution 110 becomes hydrochloric acid, and becomes part of the solution 110. That is, the chlorine gas recovery unit 15 is provided in order to reuse the chlorine gas produced in the electrolysis. The chlorine gas recovery unit 15 can adjust the supply amount of chlorine gas when chlorine gas is supplied. For example, the chlorine gas recovery unit 15 may measure the hydrogen ion exponent etc. of the solution 110 and adjust the supply amount of chlorine gas based on the measured value.

The three-way valve 25 switches the flow path through which the solution 120 flows. The three-way valve 25 has a first port 25a, a second port 25b, and a third port 25c. One end of a pipe 19e is connected to the first port 25a. The other end of the pipe 19e is connected to the electrolysis unit 14. One end of a pipe 19f is connected to the second port 25b. The other end of the pipe 19f is connected to the tank 12. One end of a pipe 19g is connected to the third port 25c. The other end of the pipe 19g is connected to the tank 13.

In the tank 13, the solution 120 is stored in the beginning. As described later, an alkali containing no metal is further added to the solution 120, and the solution 120 becomes a treatment liquid 130.

The treatment liquid 130 is a liquid in which an alkali containing no metal is further added to the solution 120 in which the concentration of hypochlorous acid has fallen within a prescribed range. The treatment liquid 130 can be produced also by a method in which the solution 120 in which the concentration of hypochlorous acid has fallen within a prescribed range is stored in the tank 13, and an alkali containing no metal is added at least one of between the tank 13 and the treatment unit 17 and in the treatment unit 17. That is, the addition of alkali may be performed at least one of in the tank 13, between the tank 13 and the treatment unit 17, and in the treatment unit 17.

One end of a pipe 19h is connected to the tank 13. The other end of the pipe 19h is connected to a pure water supply unit 26. The pure water supply unit 26 supplies pure water, for example ultrapure water, to the tank 13, and adjusts the concentration of the treatment liquid 130. The pure water supply unit 26 is not necessarily needed, and may be provided as necessary.

The alkali addition unit 16 adds an alkali containing no metal. The alkali containing no metal is, for example, an organic alkali such as TMAH and choline, ammonia, or the like.

One end of a pipe 19i is connected to the alkali addition unit 16. The other end of the pipe 19i is connected to the tank 13.

The alkali contained in the solution 110 is added in order to promote the reaction when hypochlorous acid is produced by electrolysis. In contrast, the alkali added by the alkali addition unit 16 is for suppressing the self-decomposition of hypochlorous acid. The treatment capacity can be further improved by appropriately selecting the type of the added alkali in accordance with the material of the object to be treated. Details of the treatment liquid 130 are described later.

The alkali contained in the solution 110 and the alkali added by the alkali addition unit 16 may be of the same kind or of different kinds from each other.

Details of the alkali addition by the alkali addition unit 16 are described later.

One end of a pipe 19j is connected to the tank 13. The other end of the pipe 19j is connected to a supply unit 27 such as a pump. One end of a pipe 19k is connected to the supply unit 27. The other end of the pipe 19k is connected to a nozzle 17a provided in the treatment unit 17.

The supply unit 27 supplies the treatment liquid 130 stored in the tank 13 toward the treatment unit 17. In the case where the addition of alkali is performed other than in the tank 13, the supply unit 27 supplies the solution 120 stored in the tank 13 toward the treatment unit 17.

The treatment unit 17 uses the treatment liquid 130 to perform the treatment of an object to be treated W.

The object to be treated W is, for example, a silicon wafer, a glass substrate, or the like.

The treatment of the object to be treated W is, for example, the cleaning of the object to be treated W.

Thus, the case of a cleaning apparatus in which the treatment unit 17 performs the cleaning of a silicon wafer is illustrated herein as an example.

The nozzle 17a, a mounting unit 17b, and a cover 17c are provided in the treatment unit 17.

The nozzle 17a has a discharge port for discharging the treatment liquid 130 to the object to be treated W. The mounting unit 17b on which the object to be treated W is mounted is provided to oppose the discharge port.

The mounting unit 17b is provided in the cover 17c. The mounting unit 17b can hold the object to be treated W.

The cover 17c is provided so as to surround the mounting unit 17b. The cover 17c suppresses the scattering of the treatment liquid 130 discharged from the nozzle 17a. The cover 17c collects the used treatment liquid 130. One end of a pipe 19m is connected to the bottom of the cover 17c. The other end of the pipe 19m is connected to a not-shown waste liquid treatment unit or the like.

The treatment liquid 130 is supplied to the nozzle 17a provided in the treatment unit 17 by the supply unit 27.

The contaminants etc. on the object to be treated W can be removed by discharging the treatment liquid 130 from the nozzle 17a toward the object to be treated W.

The treatment liquid 130 discharged toward the object to be treated W flows out from the periphery of the object to be treated W, and is collected into the cover 17c. The used treatment liquid 130 collected is discharged via the pipe 19m. The used treatment liquid 130 discharged may be disposed of or reused.

A drive unit that rotates the mounting unit 17b may be provided to build a spin-type cleaning apparatus. It is also possible to provide a drive unit that moves the position of the nozzle 17a.

Although the treatment unit 17 illustrated in FIG. 1 is a sheet-fed cleaning apparatus, also a batch-type cleaning apparatus is possible in which a plurality of objects to be treated W are immersed at one time.

The treatment unit 17 is not limited to cleaning apparatuses but may be altered as appropriate. For example, the treatment unit 17 may be configured as a wet ashing apparatus, a wet etching apparatus, or the like.

Although a wafer has been illustrated as the object to be treated W, the object to be treated W is not limited thereto but may be changed as appropriate. For example, the object to be treated W may be a component included in an electronic device, such as a glass substrate of a flat panel display.

Next, the operation of the treatment apparatus 1 is illustrated.

First, the solution 110 is stored in the tank 11. The solution 110 is, for example, a solution containing an alkali containing no metal, hydrochloric acid, and water. The alkali containing no metal is, for example, an organic alkali such as TMAH and choline, ammonia, or the like.

Next, the hydrochloric acid concentration of the solution 110 stored in the tank 11 is adjusted as necessary. First, the hydrogen ion exponent of the solution 110 stored in the tank 11 is measured by the chlorine gas recovery unit 15. Then, in the case where the hydrogen ion exponent of the solution 110 is lower than the specified value, chlorine gas is supplied from the chlorine gas recovery unit 15 so that the hydrogen ion exponent of the solution 110 may become the specified value. For example, when the hydrogen ion exponent of the solution 110 is ph 7, chlorine gas is supplied from the chlorine gas recovery unit 15 so that the hydrogen ion exponent of the solution 110 may become ph 6.

Next, the valve 20 is opened to supply the solution 110 in the tank 11 to the tank 12 via the pipe 19a, the valve 20, and the pipe 19b.

Next, the supply unit 21 is put into operation to supply the solution 110 in the tank 12 to the electrolysis unit 14 via the pipe 19c, the supply unit 21, and the pipe 19d.

Next, the DC power source 23 is put into operation to apply a voltage to the anode electrode 22a and the cathode electrode 22b. Thereby, the solution 110 is electrolyzed to produce the solution 120 in which the concentration of hypochlorous acid has been increased.

For the conditions of the electrolysis, for example, the concentration of the mixed liquid of TMAH and hydrochloric acid in the solution 110 may be approximately 20 wt %; the electrolysis time may be approximately 60 minutes; the applied voltage may be approximately 15 V; and the current density may be approximately 0.32 A/cm².

In the electrolysis, the reaction illustrated in Formula 1 below occurs.

2Cl⁻->Cl₂+2e⁻ (1)

For the chlorine molecule (Cl₂) produced in Formula 1, the reaction illustrated in Formula 2 below occurs.

Cl₂+H₂O<=>HCl+HClO (2)

Hypochlorous acid is produced by the reaction illustrated in Formula 2. Thereby, the solution 120 in which the concentration of hypochlorous acid has been increased is produced in the anode chamber 18a.

The alkali containing no metal added to the solution 110 produces counter ions for promoting the reaction illustrated in Formula 2.

That is, under alkaline conditions, the equilibrium is inclined to the right side of Formula 2; therefore, the production of hypochlorous acid is promoted.

Chlorine gas (Cl₂) is produced by the reaction illustrated in Formula 1. The produced chlorine gas is supplied to the chlorine gas recovery unit 15 via the pipe 28a.

The solution 120 that has undergone electrolysis is supplied to the tank 12 via the pipe 19e, the three-way valve 25, and the pipe 19f.

Thus, the solution 120 is circulated via the pipe 19c, the supply unit 21, the pipe 19d, the electrolysis unit 14, the pipe 19e, the three-way valve 25, and the pipe 19f. The circulation is repeated until the concentration of hypochlorous acid in the solution 120 falls within a prescribed range.

The concentration of hypochlorous acid in the solution 120 can be found through the hydrogen ion exponent, for example.

Thus, the concentration of hypochlorous acid in the solution 120 can be controlled on the basis of the hydrogen ion exponent.

For example, when the hydrogen ion exponent of the solution 120 immediately after supplied from the tank 11 is ph 6, the circulation is repeated until the hydrogen ion exponent becomes ph 2.

When the concentration of hypochlorous acid in the solution 120 has fallen within a prescribed range, the flow path is switched by the three-way valve 25. The solution 120 in which the concentration of hypochlorous acid has fallen within a prescribed range is supplied to the tank 13 via the three-way valve 25 and the pipe 19g.

Next, an alkali containing no metal is added by the alkali addition unit 16 to produce the treatment liquid 130. The alkali containing no metal is, for example, an organic alkali such as TMAH and choline, ammonia, or the like. The addition amount of the alkali containing no metal can be found through the hydrogen ion exponent, for example.

For example, the hydrogen ion exponent of the treatment liquid 130 may be measured by the alkali addition unit 16, and the alkali may be added until the hydrogen ion exponent becomes a prescribed value.

For example, when the hydrogen ion exponent of the treatment liquid 130 is ph 2, the alkali is supplied until the hydrogen ion exponent becomes ph 10.

Next, the supply unit 27 is put into operation to supply the treatment liquid 130 to the nozzle 17a of the treatment unit 17 via the pipe 19j, the supply unit 27, and the pipe 19k. The treatment liquid 130 supplied to the nozzle 17a is discharged toward the object to be treated W. The treatment liquid 130 discharged from the nozzle 17a comes into contact with the surface of the object to be treated W, and treatment is performed.

The treatment liquid 130 contains hypochlorous acid. Therefore, the reaction illustrated in Formula 3 below occurs at the surface of the object to be treated W.

ClO⁻+2H⁺2e⁻->Cl⁻+H₂O (3)

Hypochlorous acid has a strong oxidation action, and can remove the metals, organic substances, etc. on the surface of the object to be treated W.

The used treatment liquid 130 is collected into the cover 17c. The used treatment liquid 130 collected is discharged from the cover 17c. The used treatment liquid 130 discharged may be disposed of or reused.

Next, the treatment liquid 130 is further described.

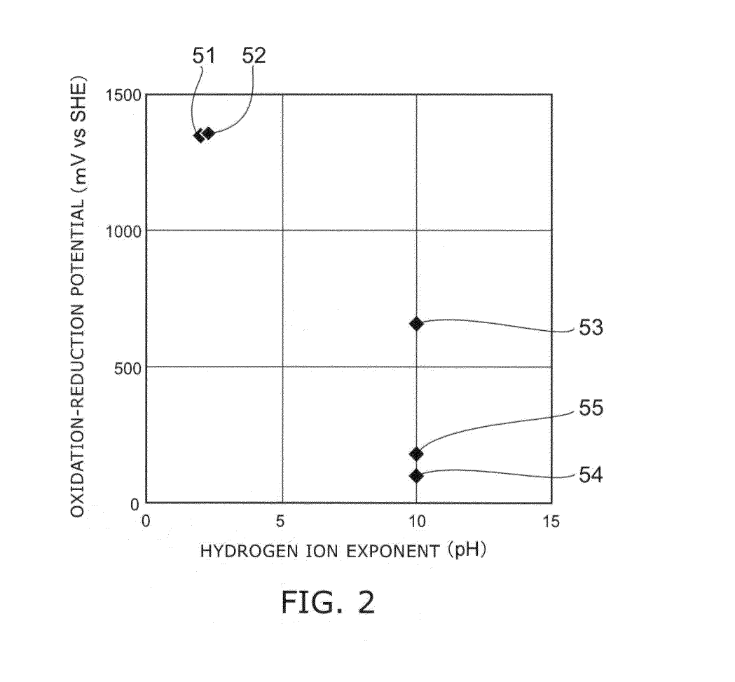

FIG. 2 is a graph for illustrating characteristics of the treatment liquid 130.

The vertical axis represents the oxidation-reduction potential, and the horizontal axis represents the hydrogen ion exponent.

A solution 51 and a solution 52 in FIG. 2 are the solution 120 in which the concentration of hypochlorous acid has fallen within a prescribed range. That is, the solution 51 and the solution 52 are the solution 120 before an alkali is added by the alkali addition unit 16. In this case, the solution 51 is the case where the solution 110 containing TMAH, hydrochloric acid, and water is electrolyzed. The solution 52 is the case where the solution 110 containing choline, hydrochloric acid, and water is electrolyzed.

A solution 53 and a solution 54 in FIG. 2 are the treatment liquid 130. The solution 53 and the solution 54 are a solution in which an alkali containing no metal is added to the solution 120 in which the concentration of hypochlorous acid has fallen within a prescribed range. That is, the solution 53 and the solution 54 are the case of the treatment liquid 130 after the alkali is added by the alkali addition unit 16. In this case, the solution 53 is the case where the solution 110 containing TMAH, hydrochloric acid, and water is electrolyzed and TMAH is added. The solution 54 is the case where the solution 110 containing choline, hydrochloric acid, and water is electrolyzed and choline is added.

A solution 55 in FIG. 2 is the case of a chemical liquid A according to a comparative example (a mixed liquid of choline, hydrogen peroxide, and water).

As shown in FIG. 2, the oxidation-reduction potentials of the solution 51 and the solution 52 before the alkali is added are higher than the oxidation-reduction potentials of the solution 53 and the solution 54 after the alkali is added. That is, the oxidizing power of the solution 51 and the solution 52, which are the solution 120, is stronger than the oxidizing power of the solution 53 and the solution 54, which are the treatment liquid 130.

However, under acidic conditions, hypochlorous acid will self-decompose, and therefore the oxidizing power may decrease with time.

On the other hand, under alkaline conditions, the self-decomposition of hypochlorous acid can be suppressed, and therefore the quality of the treatment liquid 130 can be stabilized. Furthermore, the preservation of the treatment liquid 130 becomes possible.

In this case, the solution 53 has a lower oxidation-reduction potential than the solution 51, but has a higher oxidation-reduction potential than the solution 55 (the chemical liquid A). Therefore, when the solution 53 in which the solution 110 containing TMAH, hydrochloric acid, and water is electrolyzed and TMAH is added is used, the treatment capacity can be made higher than when the solution 55 is used, and the quality can be stabilized.

On the other hand, when the solution 51 and the solution 52 are used, the treatment capacity can be made still higher. In the case of the solution 51 and the solution 52, since hypochlorous acid may self-decompose, they can be used in such a way that, for example, the solution 51 and the solution 52 produced are used for treatment as they are.

The findings obtained by the inventors have revealed that the self-decomposition of hypochlorous acid can be suppressed by setting the hydrogen ion exponent of the treatment liquid 130 to pH 4 or more. In this case, to enhance the effect of suppressing the self-decomposition of hypochlorous acid, the hydrogen ion exponent of the treatment liquid 130 is preferably set to pH 7 or more. As the hydrogen ion exponent of the treatment liquid 130 becomes higher, the effect of suppressing the self-decomposition of hypochlorous acid becomes higher.

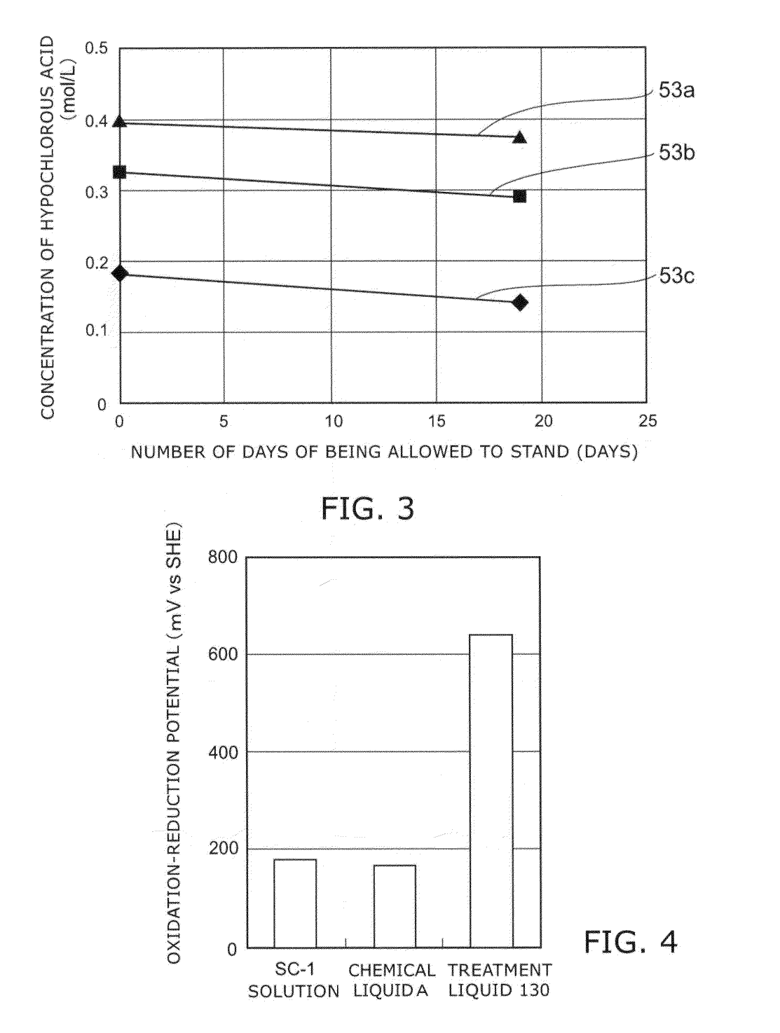

FIG. 3 is a graph illustrating relationships between the concentration of hypochlorous acid and the time of being allowed to stand in the case where the hydrogen ion exponent of the treatment liquid 130 is pH 10.

The vertical axis represents the concentration of hypochlorous acid, and the horizontal axis represents the number of days of being allowed to stand at room temperature.

Solutions 53a to 53c in FIG. 3 are the case where the solution 110 containing TMAH, hydrochloric acid, and water is electrolyzed and TMAH is added. The solution 53a is the case where the initial concentration of hypochlorous acid is approximately 0.39 mol/L. The solution 53b is the case where the initial concentration of hypochlorous acid is approximately 0.32 mol/L. The solution 53c is the case where the initial concentration of hypochlorous acid is approximately 0.18 mol/L.

As shown in FIG. 3, under alkaline conditions in which the hydrogen ion exponent is pH 10, the reduction in the concentration of hypochlorous acid can be suppressed even upon being allowed to stand for 19 days at room temperature. The higher the initial concentration of hypochlorous acid is, the smaller the reduction in the concentration of hypochlorous acid is. For example, the reduction in the concentration of hypochlorous acid in the case of being allowed to stand for 19 days was approximately 5.1% in the solution 53a, approximately 12.5% in the solution 53b, and approximately 22% in the solution 53c.

FIG. 4 is a graph for illustrating the treatment capacity of the treatment liquid in the case where the hydrogen ion exponent is pH 10.

The vertical axis represents the oxidation-reduction potential, and the horizontal axis represents the type of the treatment liquid.

An SC-1 (Standard Clean 1) solution in FIG. 4 is a mixed liquid of ammonia, hydrogen peroxide, and water (ammonia:hydrogen peroxide:water=1:1:5). The chemical liquid A is a mixed liquid of choline, hydrogen peroxide, and water (choline:hydrogen peroxide:water=1:1:5). The treatment liquid 130 is the case where the solution 110 containing TMAH, hydrochloric acid, and water is electrolyzed and TMAH is added. The hydrogen ion exponent of the SC-1 solution, the chemical liquid A, and the treatment liquid 130 is set to pH 10.

As can be seen from FIG. 4, when the treatment liquid 130 is used, a much higher oxidation-reduction potential can be obtained than when the SC-1 solution and the chemical liquid A, which are existing treatment liquids, are used. This means that the treatment liquid 130 provides a much higher treatment capacity than the SC-1 solution and the chemical liquid A, which are existing treatment liquids.

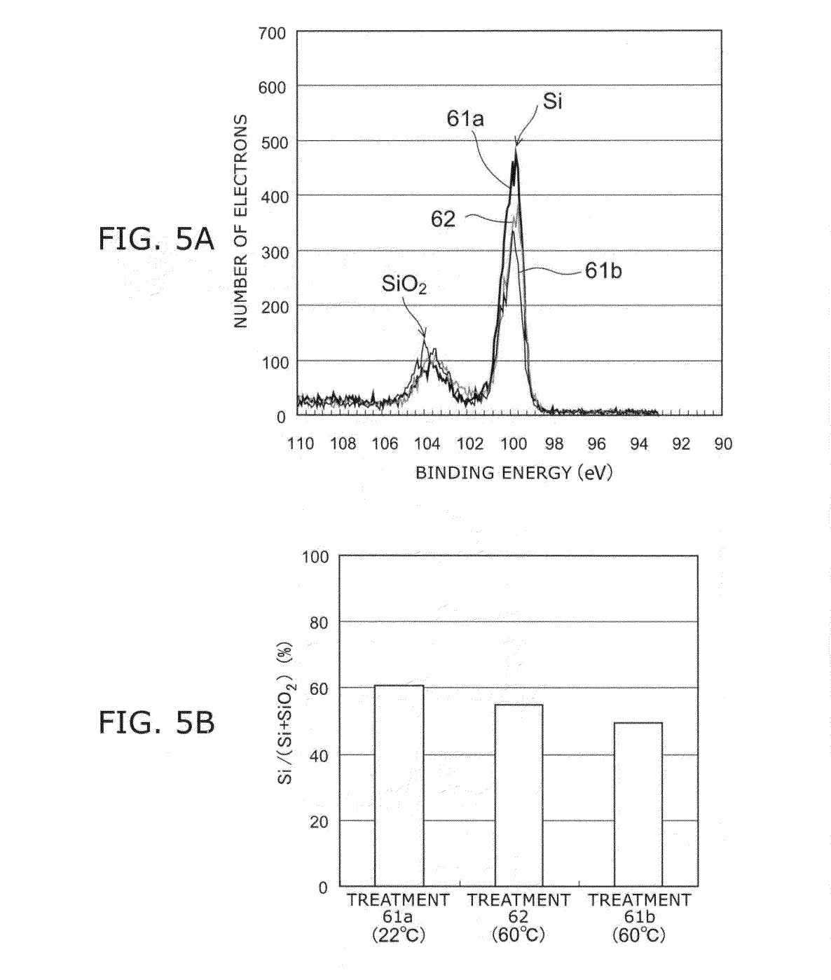

FIGS. 5A and 5B are graphs for illustrating the influence of the treatment liquid on the surface of a silicon wafer.

FIG. 5A is a graph for illustrating the state of the surface of a silicon wafer after treatment. FIG. 5A is results of measuring the surface of the silicon wafer after treatment using X-ray photoelectron spectroscopy (XPS).

The vertical axis represents the number of electrons, and the horizontal axis represents the binding energy.

Treatment 61a in FIG. 5A is the case of being treated with the treatment liquid 130 at a temperature of 22° C. The treatment liquid 130 is the case where the solution 110 containing TMAH, hydrochloric acid, and water is electrolyzed and TMAH is added. Treatment 61b is the case of being treated with the treatment liquid 130 at a temperature of 60° C. Treatment 62 is the case of being treated with the chemical liquid A at a temperature of 60° C.

As can be seen from FIG. 5A, there is no great difference in the peak value of silicon oxide (SiO₂) between the case of treatment 61a and treatment 61b and the case of treatment 62. That is, the treatment using the treatment liquid 130 and the treatment using the existing chemical liquid A are equivalent in terms of silicon (Si) at the surface of the silicon wafer being oxidized.

FIG. 5B is a graph for illustrating the proportion of the amount of silicon in the surface of the silicon wafer after treatment.

The vertical axis represents the proportion of the amount of silicon to the total amount of silicon and silicon oxide.

As can be seen from FIG. 5B, there is no great difference in the proportion of the amount of silicon between the case of treatment 61a and treatment 61b and the case of treatment 62. That is, the treatment using the treatment liquid 130 and the treatment using the existing chemical liquid A are equivalent in terms of silicon (Si) at the surface of the silicon wafer being oxidized.

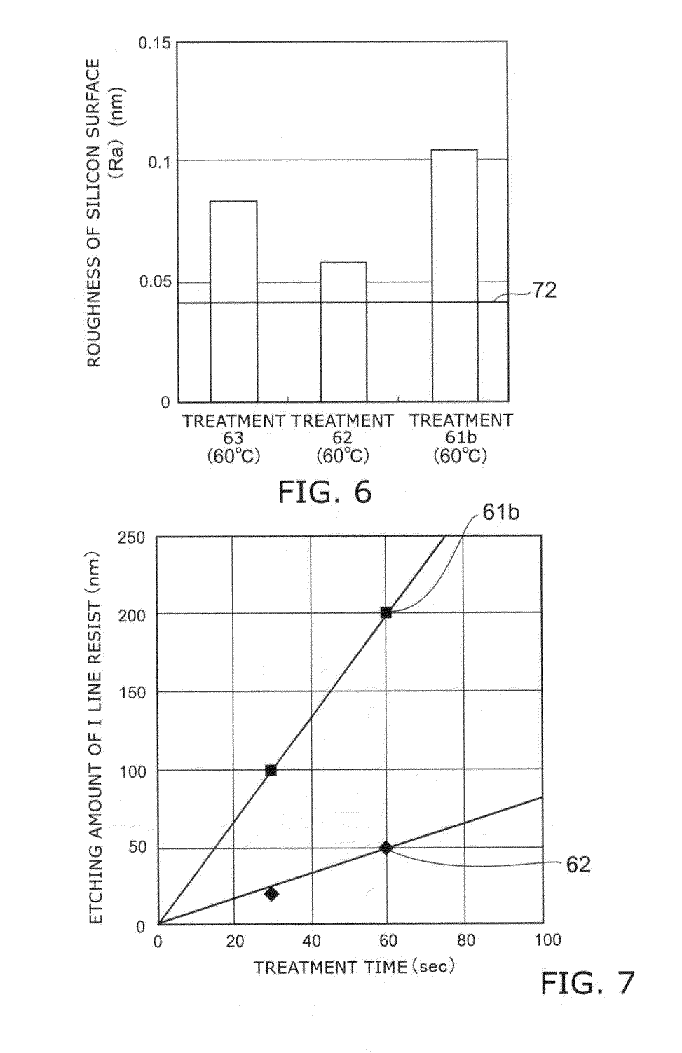

FIG. 6 is a graph for illustrating the influence of the treatment liquid on the roughness of the surface of the silicon wafer.

The vertical axis represents the center line average roughness (Ra) of the surface of the silicon wafer after treatment.

Treatment 61b is the case of being treated with the treatment liquid 130 at a temperature of 60° C. The treatment liquid 130 is the case where the solution 110 containing TMAH, hydrochloric acid, and water is electrolyzed and TMAH is added. Treatment 62 is the case of being treated with the chemical liquid A at a temperature of 60° C. Treatment 63 is the case of being treated with the SC-1 solution at a temperature of 60° C. 72 is the center line average roughness of the surface of the silicon wafer before treatment.

As can be seen from FIG. 6, the roughness of the surface of the silicon wafer in the case of treatment 61b is substantially equal to the roughness of the surface of the silicon wafer in the case of treatment 62 and treatment 63.

That is, the treatment using the treatment liquid 130 and the treatment using the existing chemical liquid A or the existing SC-1 solution are equivalent in terms of the roughness of the surface of the silicon wafer.

As can be seen from FIG. 5A, FIG. 5B, and FIG. 6, the influence of the treatment using the treatment liquid 130 on the surface of the silicon wafer is equivalent to that in the case of the treatment using the existing chemical liquid A or the existing SC-1 solution.

FIG. 7 is a graph for illustrating the organic substance removal capacity of the treatment liquid.

The vertical axis represents the etching amount of an I line resist, and the horizontal axis represents the treatment time.

Treatment 61b in FIG. 7 is the case of being treated with the treatment liquid 130 at a temperature of 60° C. The treatment liquid 130 is the case where the solution 110 containing TMAH, hydrochloric acid, and water is electrolyzed and TMAH is added. Treatment 62 is the case of being treated with the chemical liquid A at a temperature of 60° C.

The etching amount was measured using a level difference meter. The measurement error is ±30 nm for treatment 61b and ±20 nm for treatment 62.

As can be seen from FIG. 7, when treatment 61b using the treatment liquid 130 is performed, the resist can be removed in a much larger amount than when treatment 62 using the existing chemical liquid A is performed.

This means that the treatment liquid 130 has a high capacity of organic substance removal.

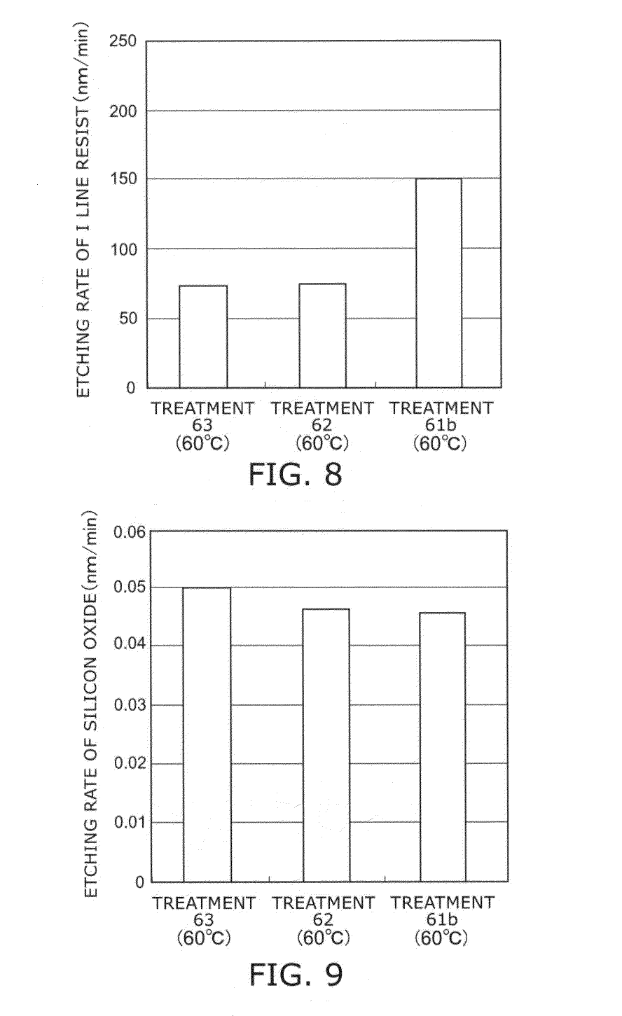

FIG. 8 is a graph for illustrating the organic substance removal capacity of the treatment liquid.

The vertical axis represents the etching rate of an I line resist.

Treatment 61b in FIG. 8 is the case of being treated with the treatment liquid 130 at a temperature of 60° C. The treatment liquid 130 is the case where the solution 110 containing TMAH, hydrochloric acid, and water is electrolyzed and TMAH is added. Treatment 62 is the case of being treated with the chemical liquid A at a temperature of 60° C. Treatment 63 is the case of being treated with the SC-1 solution at a temperature of 60° C.

As can be seen from FIG. 8, the etching rate of treatment 61b is two times higher than the etching rate of treatment 62 or treatment 63. Thus, the treatment time of treatment 61b using the treatment liquid 130 is only approximately half the treatment time of treatment 62 using the existing chemical liquid A and treatment 63 using the SC-1 solution.

FIG. 9 is a graph for illustrating the silicon oxide removal capacity of the treatment liquid.

The vertical axis represents the etching rate of silicon oxide (a thermally oxidized film).

Treatment 61b in FIG. 9 is the case of being treated with the treatment liquid 130 at a temperature of 60° C. The treatment liquid 130 is the case where the solution 110 containing TMAH, hydrochloric acid, and water is electrolyzed and TMAH is added. Treatment 62 is the case of being treated with the chemical liquid A at a temperature of 60° C. Treatment 63 is the case of being treated with the SC-1 solution at a temperature of 60° C.

As can be seen from FIG. 9, the etching rate of treatment 61b can be made substantially equal to the etching rate of treatment 62 or treatment 63. Thus, the treatment time of treatment 61b using the treatment liquid 130 can be made substantially equal to the treatment time of treatment 62 using the existing chemical liquid A and treatment 63 using the SC-1 solution.

As can be seen from FIG. 7 to FIG. 9, the treatment liquid 130 has a high removal capacity as compared to the existing chemical liquid A or the existing SC-1 solution.

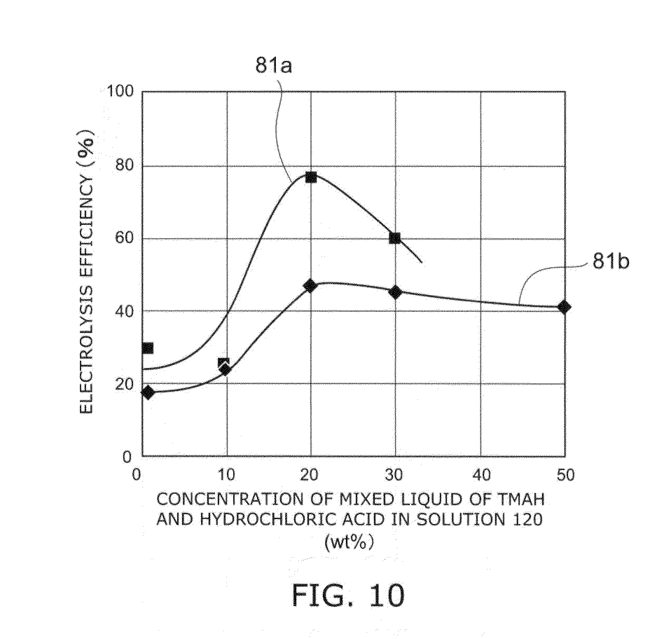

FIG. 10 is a graph for illustrating the electrolysis efficiency in the electrolysis unit 14.

The vertical axis represents the electrolysis efficiency, and the horizontal axis represents the concentration of the mixed liquid of TMAH and hydrochloric acid in the solution 120.

Electrolysis treatment 81a in FIG. 10 is the case where the applied voltage is 15 V and the electrolysis time is 30 minutes. Electrolysis treatment 81b is the case where the applied voltage is 15 V and the electrolysis time is 60 minutes.

As can be seen from FIG. 10, when the concentration of the mixed liquid of TMAH and hydrochloric acid in the solution 120 is set to 20 wt % or more, a high electrolysis efficiency can be obtained.

When the concentration of the mixed liquid of TMAH and hydrochloric acid in the solution 120 is set to 20 wt % or more, hypochlorous acid can be produced with good efficiency.

When the electrolysis time is set to 30 minutes, a high electrolysis efficiency can be obtained. When the electrolysis time is set to 60 minutes, the electrolysis efficiency can be stabilized.

In the embodiment, since the solution 120 containing hypochlorous acid is produced by performing electrolysis, the productivity of the treatment liquid 130 can be enhanced.

### Second Embodiment

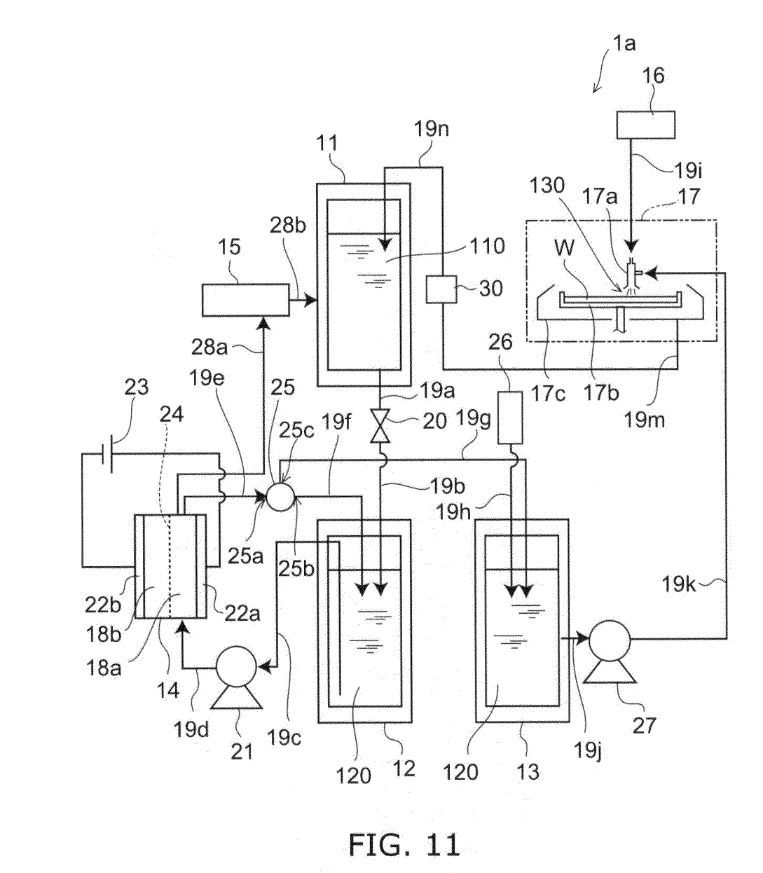

FIG. 11 is a schematic diagram for illustrating a treatment apparatus la according to a second embodiment.

As shown in FIG. 11, the tank 11, the tank 12, the tank 13, the electrolysis unit 14, the chlorine gas recovery unit 15, the alkali addition unit 16, and the treatment unit 17 are provided in the treatment apparatus 1a.

In the case of the treatment apparatus 1 described above, the alkali addition unit 16 is connected to the tank 13 via the pipe 19i. In contrast, in the case of the treatment apparatus is according to the embodiment, the alkali addition unit 16 is connected to the nozzle 17a of the treatment unit 17 via a pipe 19i.

Therefore, the solution 120 is stored in the tank 13. In this case, the treatment liquid 130 is produced in the nozzle 17a.

That is, in the case of what is illustrated in FIG. 11, the tank 12 serves as a production tank of the solution 120, and the tank 13 serves as a buffer tank of the solution 120.

In the case of the treatment apparatus 1, the used treatment liquid 130 is discharged to a not-shown waste liquid treatment unit or the like via the pipe 19m. In contrast, in the case of the treatment apparatus la, the used treatment liquid 130 is supplied to the tank 11 via a pipe 19m, a filter unit 30, and a pipe 19n.

The filter unit 30 filters the removed substances (e.g. a resist etc.) contained in the used treatment liquid 130.

One end of the pipe 19m is connected to the cover 17c. The other end of the pipe 19m is connected to the filter unit 30.

One end of the pipe 19n is connected to the filter unit 30. The other end of the pipe 19n is connected to the tank 11.

The used treatment liquid 130 discharged from the treatment unit 17 is filtered by the filter unit 30. The filtered treatment liquid 130 is supplied to the tank 11, and is reused.

As described above, an alkali containing no metal is added by the alkali addition unit 16 in order to suppress the self-decomposition of hypochlorous acid.

In this case, the treatment capacity can be further improved by appropriately selecting the type of the added alkali in accordance with the material of the object to be treated.

For example, when TMAH is added as illustrated in FIG. 7 and FIG. 8, the treatment capacity to organic substances such as a resist can be improved.

When ammonia is added, the treatment capacity to metals such as copper (Cu) and nickel (Ni) can be improved.

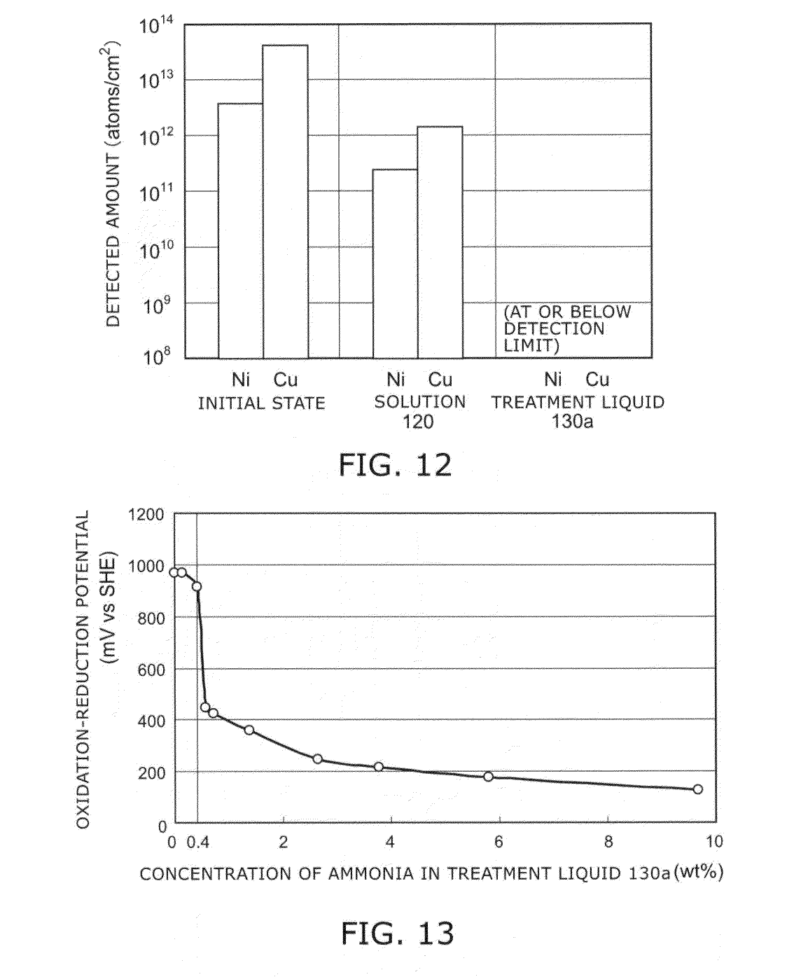

FIG. 12 is a graph for illustrating the treatment capacity in the case where ammonia is added.

The vertical axis represents the detected amount.

The detection was performed using total reflection X-ray fluorescence spectrometry (TXRF).

The initial state in FIG. 12 is a state where a nitric acid aqueous solution containing copper and nickel is spin-applied to the surface of a silicon wafer with a diameter dimension of 200 mm.

The solution 120 is a solution in which the solution 110 containing TMAH, hydrochloric acid, and water is electrolyzed. That is, the solution 120 is a solution before an alkali is added by the alkali addition unit 16.

A treatment liquid 130a is a liquid in which the solution 110 containing TMAH, hydrochloric acid, and water is electrolyzed and aqueous ammonia is added.

As can be seen from FIG. 12, the copper and nickel attached to the surface of the silicon wafer can be removed when the solution 110 containing hypochlorous acid is used.

The copper and nickel attached to the surface of the silicon wafer can be removed more satisfactorily when the treatment liquid 130a in which aqueous ammonia is added is used.

However, it has been found that the oxidation-reduction potential is reduced when ammonia is added.

FIG. 13 is a graph for illustrating the influence of ammonia addition.

The vertical axis represents the oxidation-reduction potential, and the horizontal axis represents the concentration of ammonia in the treatment liquid 130a.

As can be seen from FIG. 13, when the concentration of ammonia is made too high, the oxidation-reduction potential is reduced. This means that the treatment capacity of the treatment liquid 130a is reduced.

Thus, the concentration of ammonia in the treatment liquid 130a is preferably set to 0.4 wt % or less.

When ammonia is added, the reaction illustrated in Formula 4 occurs to produce nitrogen gas.

2NH₃+3(CH₃)₄N⁺ClO⁻->N₂+3(CH₃)₄N⁺Cl⁻+3H₂O (4)

When nitrogen gas is produced, the flow rate control of the treatment liquid 130a may become difficult.

According to the findings obtained by the inventors, when ammonia is added in a position as close as possible to the object to be treated W, the influence of nitrogen gas can be suppressed.

In addition, it becomes possible to supply the treatment liquid 130a to the object to be treated W before the reduction in the oxidation-reduction potential described in FIG. 13 progresses. That is, when ammonia is added in a position as close as possible to the object to be treated W, the concentration of ammonia can be made higher than 0.4 wt %.

In the case of the treatment apparatus 1a illustrated in FIG. 11, the alkali is supplied to the nozzle 17a.

Therefore, the treatment liquid 130a can be supplied to the object to be treated W before the reduction in the oxidation-reduction potential progresses. Consequently, the effect of ammonia addition can be enjoyed sufficiently; therefore, a treatment excellent in the removal of metal can be performed. Furthermore, the supply of the treatment liquid 130a can be stabilized.

In the case where TMAH is added, since the reduction in the oxidation-reduction potential is small as illustrated in FIG. 3, a sufficient treatment capacity can be exhibited both by the configuration of the treatment apparatus 1 and by the configuration of the treatment apparatus 1a.

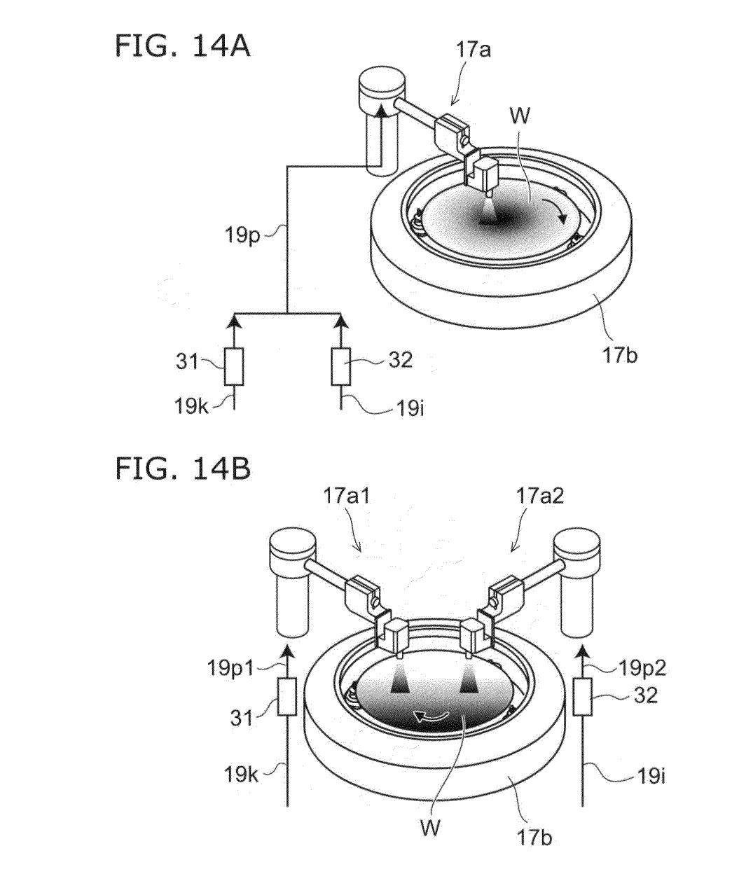

FIGS. 14A and 14B are schematic views for illustrating the position of alkali addition.

FIG. 14A is the case where the alkali is added immediately before the upstream side of the nozzle 17a.

FIG. 14B is the case where the alkali is added on the surface of the object to be treated W.

In the case of what is illustrated in FIG. 14A, one end of the pipe 19k described above is connected to a flow rate control unit 31. One end of the pipe 19i described above is connected to a flow rate control unit 32. One end of a pipe 19p is branched into two, and the flow rate control unit 31 and the flow rate control unit 32 are connected individually to the two ends. The other end of the pipe 19p is connected to the nozzle 17a. The solution 120 is supplied to the nozzle 17a via the pipe 19k, the flow rate control unit 31, and the pipe 19p. The alkali is supplied to the nozzle 17a via the pipe 19i, the flow rate control unit 32, and the pipe 19p. Thus, the treatment liquids 130 and 130a are produced in the pipe 19p provided immediately before the upstream side of the nozzle 17a. At this time, the concentration of alkali can be adjusted by controlling the supply amount of at least one of the solution 120 and the alkali by means of the flow rate control unit 31 and the flow rate control unit 32.

In the case of what is illustrated in FIG. 14B, one end of the pipe 19k described above is connected to the flow rate control unit 31. One end of a pipe 19p1 is connected to the flow rate control unit 31. The other end of the pipe 19p1 is connected to a nozzle 17a1. One end of the pipe 19i described above is connected to the flow rate control unit 32. One end of a pipe 19p2 is connected to the flow rate control unit 32. The other end of the pipe 19p2 is connected to a nozzle 17a2. The solution 120 is supplied to the nozzle 17a1 via the pipe 19k, the flow rate control unit 31, and the pipe 19p1. The alkali is supplied to the nozzle 17a2 via the pipe 19i, the flow rate control unit 32, and the pipe 19p2. Thus, the solution 120 and the alkali are mixed together on the surface of the object to be treated W; thereby, the treatment liquids 130 and 130a are produced. At this time, the concentration of alkali can be adjusted by controlling the supply amount of at least one of the solution 120 and the alkali by means of the flow rate control unit 31 and the flow rate control unit 32.

The position of alkali addition is not limited to those illustrated.

For example, the alkali containing no metal may be further added in at least one of the interior of the treatment unit 17 and the portion where the solution 120 is introduced into the treatment unit 17.

The interior of the treatment unit 17 is, for example, the cases illustrated in FIG. 11 and FIGS. 14A and 14B.

As the portion where the solution 120 is introduced into the treatment unit 17, the case illustrated in FIG. 1, the neighborhood of the portion where the pipe 19k is connected to the treatment unit 17, and the like may be illustrated.

In the embodiment, since the solution 120 containing hypochlorous acid is produced by performing electrolysis, the productivity of the treatment liquid 130a can be enhanced.

### Third Embodiment

Next, a method for manufacturing a treatment liquid according to a third embodiment is illustrated.

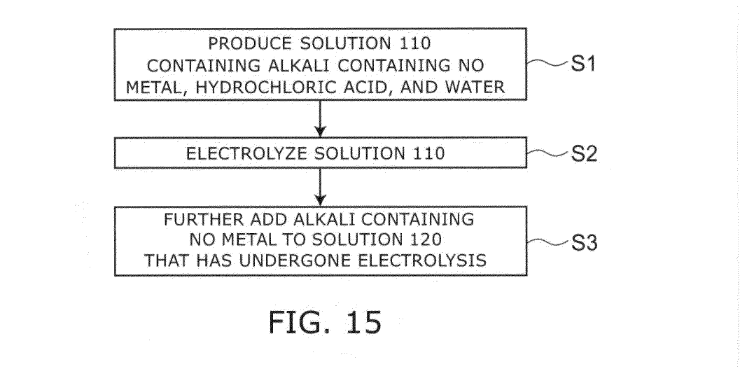

FIG. 15 is a flow chart for illustrating a method for manufacturing a treatment liquid according to the third embodiment.

First, the solution 110 containing an alkali containing no metal, hydrochloric acid, and water is produced (step S1).

The alkali containing no metal is, for example, an organic alkali such as TMAH and choline, ammonia, or the like.

The hydrochloric acid concentration of the solution 110 is adjusted as necessary.

Next, the solution 110 is electrolyzed (step S2).

By the solution 110 being electrolyzed, the solution 120 in which the concentration of hypochlorous acid has been increased is produced.

For the conditions of the electrolysis, for example, the concentration of the mixed liquid of TMAH and hydrochloric acid in the solution 110 may be approximately 20 wt %; the electrolysis time may be approximately 60 minutes; the applied voltage may be approximately 15 V; and the current density may be approximately 0.32 A/cm².

The solution may be circulated between the electrolysis unit 14 that performs electrolysis and the tank 12 that stores the solution.

The chlorine gas produced when electrolysis is performed may be recovered, and the recovered chlorine gas may be supplied to the solution.

Next, an alkali containing no metal is further added to the solution 120 that has undergone electrolysis (step S3).

The alkali containing no metal is, for example, an organic alkali such as TMAH and choline, ammonia, or the like.

In this case, the type of the added alkali may be selected in accordance with the material of the object to be treated. For example, in the case where an organic substance such as a resist is removed, TMAH may be added. Furthermore, for example, in the case where a metal such as copper and nickel is removed, ammonia may be added. Thereby, the treatment capacity can be further improved.

The alkali containing no metal may be added immediately before performing the treatment of the object to be treated W.

For example, the alkali containing no metal may be further added in at least one of the interior of the treatment unit 17 and the portion where the solution 120 is introduced into the treatment unit 17.

As the interior of the treatment unit 17, for example, the nozzle 17a, the surface to be treated of the object to be treated W (e.g. the surface of a silicon wafer), and the like may be illustrated.

As the portion where the solution 120 is introduced into the treatment unit 17, the neighborhood of the portion where the pipe 19k is connected to the treatment unit 17 and the like may be illustrated.

Thus, the treatment liquids 130 and 130a can be manufactured.

The matters in the processes may be the same as those described above, and a detailed description is omitted.

In the embodiment, since the solution 120 containing hypochlorous acid is produced by performing electrolysis, the productivity of the treatment liquids 130 and 130a can be enhanced.

### Fourth Embodiment

Next, a method for manufacturing an electronic device according to a fourth embodiment is illustrated.

As the method for manufacturing an electronic device, for example, a method for manufacturing a semiconductor device, a method for manufacturing a flat panel display, and the like may be illustrated. For example, the manufacturing process of a semiconductor device includes a process that forms a pattern on the surface of a silicon wafer by film-formation, resist application, light exposure, development, etching, resist removal, etc. in what is called a preprocess, a test process, a cleaning process, a heat treatment process, an impurity introduction process, a diffusion process, a planarization process, etc. What is called a postprocess includes an assembly process of dicing, mounting, bonding, sealing, etc., an inspection process that inspects functions and reliability, etc.

In this case, for example, the treatment liquids 130 and 130a manufactured by the method for manufacturing a treatment liquid described above may be used in the cleaning process.

For example, organic substances, metals, etc. attached to the surface of a silicon wafer can be removed using the treatment liquids 130 and 130a.

Furthermore, for example, a thermally oxidized film etc. existing on the surface of a silicon wafer can be removed using the treatment liquids 130 and 130a.

The processes other than the method for manufacturing a treatment liquid described above can use known art of the respective processes, and a detailed description thereof is omitted.

In the embodiment, since treatment can be performed using the treatment liquids 130 and 130a having a high treatment capacity, the productivity of electronic devices can be enhanced.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions. Moreover, above-mentioned embodiments can be combined mutually and can be carried out.

What is claimed is:

1. A treatment apparatus comprising:
an electrolysis unit including an anode electrode and a cathode electrode and configured to electrolyze a solution containing an alkali containing no metal, hydrochloric acid, and water;
an alkali addition unit configured to further add the alkali containing no metal to a solution that has undergone the electrolysis; and
a treatment unit configured to perform treatment of an object to be treated using a solution that has undergone the electrolysis and in which the alkali containing no metal is further added.

2. The apparatus according to claim 1, wherein the alkali addition unit further adds the alkali containing no metal in at least one of an interior of the treatment unit and a portion where a solution that has undergone the electrolysis is introduced into the treatment unit.

3. The apparatus according to claim 1, further comprising:
a first tank configured to store the solution; and
a supply unit configured to supply the solution to the electrolysis unit,
the supply unit being configured to circulate the solution between the electrolysis unit and the first tank.

4. The apparatus according to claim 1, further comprising a chlorine gas recovery unit configured to recover chlorine gas produced in the electrolysis unit.

5. The apparatus according to claim 1, further comprising a second tank configured to store the solution to be supplied to the first tank,
the chlorine gas recovery unit being configured to supply the recovered chlorine gas to the second tank.

6. The apparatus according to claim 5, further comprising a filter unit provided between the treatment unit and the second tank and configured to remove an impurity from a used solution discharged from the treatment unit.

7. The apparatus according to claim 1, wherein the alkali containing no metal is at least one of an organic alkali and ammonia.

8. The apparatus according to claim 7, wherein the organic alkali is TMAH (tetramethylammonium hydroxide) or choline.

9. The apparatus according to claim 1, wherein a solution that has undergone the electrolysis contains hypochlorous acid.

10. The apparatus according to claim 1, wherein a solution that has undergone the electrolysis and in which the alkali containing no metal is further added has a hydrogen ion exponent of pH 4 or more.

11. The apparatus according to claim 1, wherein a solution that has undergone the electrolysis and in which the alkali containing no metal is further added has a hydrogen ion exponent of pH 7 or more.

12. The apparatus according to claim 7, wherein a concentration of the ammonia in the solution that has undergone the electrolysis and in which the ammonia is further added is 0.4 wt % or less.

13. The apparatus according to claim 8, wherein a concentration of a mixed liquid of the TMAH and the hydrochloric acid in the solution containing the TMAH, the hydrochloric acid, and the water is 20 wt % or more.

14. A method for manufacturing a treatment liquid comprising:
electrolyzing a solution containing an alkali containing no metal, hydrochloric acid, and water; and
further adding the alkali containing no metal to a solution that has undergone the electrolysis.

15. The method according to claim 14, wherein
in the further adding the alkali containing no metal,
the alkali containing no metal is further added immediately before treatment of an object to be treated is performed.

16. The method according to claim 14, further comprising circulating the solution between an electrolysis unit configured to perform the electrolysis and a first tank configured to store the solution.

17. The method according to claim 14, wherein chlorine gas produced when the electrolysis is performed is recovered and the recovered chlorine gas is supplied to the solution.

18. The method according to claim 14, wherein the alkali containing no metal is at least one of an organic alkali and ammonia.

19. The method according to claim 14, wherein an organic alkali is TMAH (tetramethylammonium hydroxide) or choline.

20. A method for manufacturing an electronic device comprising performing treatment of an object to be treated using a treatment liquid manufactured by the method according to claim 14.
